(19) United States
(12) Patent Application Publication
(10) Pub. No.: US 2025/0199293 A1
(43) Pub. Date: Jun. 19, 2025

(54) METHOD FOR OPERATING AN OPTICAL COMPONENT, AND OPTICAL COMPONENT

(71) Applicant: Carl Zeiss SMT GmbH, Oberkochen (DE)

(72) Inventor: Ralf NOLTEMEYER, Herrenberg (DE)

(21) Appl. No.: 19/072,268

(22) Filed: Mar. 6, 2025

Related U.S. Application Data
(63) Continuation of application No. PCT/EP2023/073561, filed on Aug. 28, 2023.

(30) Foreign Application Priority Data
Sep. 9, 2022 (DE) 10 2022 209 391.7

(51) Int. Cl. G02B 26/08; G03F 7/00

(52) U.S. Cl. CPC G02B 26/0841; G03F 7/70266

(57) ABSTRACT

A method of operating an optical component having a mirror element, a substrate for carrying the mirror element, an actuator device for tilting the mirror element about one or two tilt axes, and a sensor device having a sensor electrode structure for detecting a tilt angle of the mirror element based on changes in capacitance. The sensor electrode structure in this case comprises a plurality of active sensor electrodes and a plurality of passive sensor electrodes. According to the disclosure, the passive sensor electrodes are subjected to different voltages during operation of the optical component.

### CROSS-REFERENCE TO RELATED APPLICATIONS

The present application is a continuation of, and claims benefit under 35 USC 120 to, international application No. PCT/EP2023/073561, filed Aug. 28, 2023, which claims benefit under 35 USC 119 of German Application No. 10 2022 209 391.7, filed Sep. 9, 2022. The entire disclosure of each of these applications is incorporated by reference herein.

### FIELD

The disclosure relates to a method of operating an optical component having a mirror element, a substrate for carrying the mirror element, an actuator device for tilting the mirror element and a sensor device having a sensor electrode structure for detecting a tilt angle of the mirror element based on changes in capacitance. The disclosure also relates to an optical component and to a mirror array comprising a plurality of such optical components. Moreover, the disclosure relates to an illumination optical unit and to an illumination system for a projection exposure apparatus, and to a projection exposure apparatus.

### BACKGROUND

Depending on the application, micromirrors may be used in different applications, such as for example smartphone projectors, head-up displays, barcode readers, etc.

For EUV lithography systems, adjustable optical paths up to the reticle, also called a mask, which are able to be implemented by a micromirror array in the optical path, are often desirable.

The micromirrors may be provided with a Bragg coating that reflects the central wavelengths well. Wavelengths outside the reflection range can be absorbed and can generate heat in the micromirror. It is often desirable to dissipate this heat in a targeted manner with the lowest reasonably possible temperature resistance.

The positional accuracy of the micromirror generally depends on how well the micromirror position sensor system works. The micromirror position sensor system generally depends on manufacturing tolerances, temperature stability in combination with temperature variance and long-term stability in combination with product lifetime or the times when the device has to be recalibrated.

Document DE 10 2015 204 874 A1 relates to an actuator device for tilting a mirror element.

Document DE 10 2016 213 026 A1 relates to a sensor device for detecting a tilt angle of a mirror element.

The two documents each describe an optical component that comprises an actuator device for tilting a mirror element with two tilting degrees of freedom and a sensor device for detecting a tilt angle of the mirror element. The actuator device comprises an actuator electrode structure having actuator electrodes that are in the form of comb electrodes and form a direct drive for pivoting the mirror element. The sensor device comprises a sensor electrode structure having sensor electrodes that are likewise in the form of comb electrodes. The optical component furthermore comprises a gimbal flexure for mounting the mirror element, wherein the flexure has flexure springs and defines two tilt axes of the mirror element.

The two documents furthermore describe that the sensor electrode structure in this case comprises sensor stator electrodes that are attached to a substrate for carrying the mirror element, and sensor mirror electrodes that are attached to the mirror element. To compute the tilt angle of the mirror element, the sensor mirror electrodes are configured to bring about variable shielding of an electric field in the region of the sensor stator electrodes on the basis of the detected tilt angle of the mirror element. The sensor mirror electrodes are in this case subjected to an identical voltage. In other words, the sensor mirror electrodes have the same potential, such as for example ground potential.

### SUMMARY

A method of operating an optical component is proposed. The optical component comprises a mirror element, a substrate for carrying the mirror element, which is for example a micromirror element, an actuator device for tilting the mirror element and a sensor device having a sensor electrode structure for detecting a tilt angle of the mirror element based on changes in capacitance. A tilt angle of the mirror element corresponds to a polar angle of a spherical coordinate system. The tilt angle may in this case be azimuth-dependent.

The sensor electrode structure comprises a plurality of active sensor electrodes, such as for example two, four, six or more, and a plurality of passive sensor electrodes, such as for example two, four, six or more. The active and passive sensor electrodes can be in the form of comb electrodes. The number of active sensor electrodes can be equal to the number of passive sensor electrodes. The passive sensor electrodes can each be assigned to an active sensor electrode. The active sensor electrodes comprise sensor transmitter electrodes and sensor receiver electrodes that can each be in the form of comb electrodes. The sensor transmitter electrodes are subjected to an AC voltage so as to detect the tilt angle of the mirror element. The passive sensor electrodes may be subjected to an identical bias voltage, which can adopt a constant value. For example, the passive sensor electrodes may be grounded or kept at a voltage of 0 V. The passive sensor electrodes can be configured to bring about variable shielding of an electric field in the region of the active sensor electrodes on the basis of a detected tilt angle of the mirror element.

According to the disclosure, the passive sensor electrodes are subjected to different voltages during operation of the optical component. This can help make it possible for example to increase the actuator force used to tilt the mirror element.

The actuator device can comprise an actuator electrode structure having a plurality of active actuator electrodes, such as for example two, four, six or more, and at least one passive actuator electrode. The active actuator electrodes and the at least one passive actuator electrode are in this case configured to exert electrostatic force so as to tilt the mirror element. The active actuator electrodes and the at least one passive actuator electrode can be in the form of comb electrodes. All of the active actuator electrodes are arranged in a common plane, which is also referred to as actuator plane. In this case, the actuator device may form a direct drive for tilting the mirror element.

Active actuator electrodes should be understood here to mean the actuator electrodes that are subjected to a variable, for example controllable, for example regulatable actuator voltage so as to tilt the mirror element. Actuator electrodes that are subjected to a fixed, that is to say constant voltage, are also referred to as passive actuator electrodes. The passive actuator electrodes may for example be grounded or kept at a voltage of 0 V.

A direct drive should be understood here to mean a drive in which the actuator device is able to exert a force directly on the mirror to be displaced. For example, no force transmission mechanism is required. In other words, the drive is force-transmission-mechanism-free.

The active actuator electrodes can be attached to the substrate and the at least one passive actuator electrode is attached to the mirror element. In this case, the active actuator electrodes are also referred to as actuator stator electrodes, while the passive actuator electrode is also referred to as actuator mirror electrode.

The active sensor electrodes can be attached to the substrate and the passive sensor electrodes are attached to the mirror element. In this case, the active sensor electrodes are also referred to as sensor stator electrodes, while the passive sensor electrode is also referred to as sensor mirror electrode.

The active sensor electrodes can be arranged in the common plane in which the active actuator electrodes are arranged. The active sensor electrodes can each be assigned to an active actuator electrode.

The number of active sensor electrodes may be equal to the number of active actuator electrodes. By way of example, each active actuator electrode may be assigned to an active sensor electrode. The number of active sensor electrodes may also be different from the number of active actuator electrodes. By way of example, the number of active actuator electrodes may be greater than the number of active sensor electrodes.

The actuator device may be part of a displacement device for displacing the mirror element, or the displacement device itself. The sensor device may likewise be part of the displacement device. In other words, the sensor electrode structure is integrated into the actuator electrode structure.

The actuator device may be configured to tilt the mirror element with a single tilting degree of freedom. The mirror element can be tilted about a tilt axis. The tilt axis makes it possible to divide the common plane into two sectors. The actuator and sensor electrodes are in this case arranged symmetrically about the tilt axis. When carrying out a method according to the disclosure in this case, for example, the passive sensor electrodes in a first sector may be subjected to a first voltage and the passive sensor electrodes in a second sector may be subjected to a second voltage.

The actuator device can be configured to tilt the mirror element with two tilting degrees of freedom. In this case, the mirror element may be tilted about two tilt axes simultaneously or in temporal succession. In this case, the two tilt axes make it possible to divide the common plane into four sectors, also referred to as quadrant. The actuator and sensor electrode structure may in this case exhibit radial symmetry. In other words, the actuator or sensor electrodes may in this case be arranged symmetrically about a centre point, which is also referred to as tilt point of the mirror element. Such a design makes it possible to improve the displacement of the mirror element. Below, a displacement should be understood to mean, in general, a displacement in view of a specific degree of freedom. For example, the displacement may be pivoting, which is also referred to as tilting. In principle, the displacement may also comprise linear displacements and/or twisting of the mirror element in a mirror plane. The optical component may in this case comprise a gimbal flexure for mounting the mirror element, wherein the flexure has flexure springs and defines two tilt axes of the mirror element.

For details regarding an actuator device for tilting the mirror element with two tilting degrees of freedom and a sensor device for detecting the tilt angle of the mirror element, reference may be made to DE 10 2015 204 874 A1 and DE 10 2016 213 026 A1, which are hereby incorporated in full into the present application as part thereof.

When carrying out a method according to the disclosure in the case in which the actuator device is configured to tilt the mirror element about two tilt axes, the passive sensor electrodes in a first sector or a first quadrant may likewise be subjected to a first voltage, while the passive sensor electrodes in other sectors or other quadrants may be subjected to a second voltage. In this case, a method according to the disclosure can be applied accordingly or in a manner adapted to the passive sensor electrodes of other sectors or quadrants.

The passive sensor electrodes can be subjected to an identical bias voltage that can adopt a constant value and, during operation of the optical component, at least one of the passive sensor electrodes is subjected to an offset voltage in addition to the bias voltage.

The fact that the at least one of the passive sensor electrodes is subjected to the offset voltage can be determined on the basis of a comparison result between a target tilt angle of the mirror element and a reference value.

The at least one of the passive sensor electrodes can be subjected to the offset voltage when the target tilt angle of the mirror element is greater than the reference value. This increases the force for tilting the mirror element.

The offset voltage can adopt a predetermined constant value. As an alternative, the offset voltage may be computed on the basis of a difference between the target tilt angle of the mirror element and the detected tilt angle of the mirror element.

A further aspect of the disclosure is the provision of an optical component that is configured to carry out the method according to the disclosure. Such an optical component comprises a mirror element, a substrate for carrying the mirror element, an actuator device for tilting the mirror element and a sensor device for detecting a tilt angle of the mirror element.

A method according to the disclosure can be carried out using an optical component proposed according to the disclosure. Accordingly, features described within the scope of the optical component apply to the method and, conversely, features described within the scope of the method apply to the optical component.

Also proposed is a mirror array that comprises a plurality of optical components according to the disclosure.

Furthermore proposed is an illumination optical unit for a projection exposure apparatus for guiding illumination radiation to an object field, which illumination optical unit comprises at least one mirror array according to the disclosure.

Also proposed is an illumination system for a projection exposure apparatus, which illumination system comprises an illumination optical unit according to the disclosure and a radiation source, for example an EUV radiation source.

Additionally proposed is a microlithographic projection exposure apparatus that comprises an illumination optical unit according to the disclosure and a projection optical unit for projecting a reticle arranged in an object field into an image field.

For details regarding a possible projection exposure apparatus, reference may be made to DE 10 2015 204 874 A1 and DE 10 2016 213 026 A1, which are hereby incorporated in full into the present application as part thereof.

By virtue of a method proposed according to the disclosure, the force for tilting the mirror element, which is generated by the actuator device, can be increased by an additional offset voltage to at least one sensor mirror electrode.

This can help enable electrical softening with the sensor mirror electrodes, such that production-relevant fluctuations in spring stiffness are able to be compensated for. Electrical softening is understood to mean modifying a spring constant of a resetting spring of the articulation device by applying a voltage to the passive sensor electrodes. For example, a force generated in this way may act counter to the spring force.

This can likewise improve the temperature resistance of the spring, such that better mirror temperature dissipation is possible.

Depending on the desired target tilt angle of the mirror element, only the actuator device may be operated, such as for example with a small tilt angle. In the case of larger tilt angles, the actuator device can be operated with a “booster actuator”, which is formed by the sensor device. There may be an overlap between the two operating modes, enabling regulation in the respective range.

The increase in the force for tilting the mirror element may be used to reduce the maximum supply voltage of the actuator device or to increase the spring stiffness and thus to reduce thermal resistance.

### BRIEF DESCRIPTION OF THE DRAWINGS

Embodiments of the disclosure are explained in more detail with reference to the drawings and the following description. In the figures:

FIG. 1 shows a side view of an optical component according to the disclosure;

FIG. 2 shows a schematic sectional illustration of the optical component according to FIG. 1;

FIG. 3.1 shows a diagram of tilt signals;

FIG. 3.2 shows a temporal profile of the target tilt angle of the mirror element;

FIG. 3.3 shows a temporal profile of a first voltage applied to an active actuator electrode;

FIG. 3.4 shows a temporal profile of a second voltage applied to a passive sensor electrode; and

FIG. 3.5 shows a temporal profile of the detected tilt angle of the mirror element.

### DETAILED DESCRIPTION

In the following description of the embodiments of the disclosure, identical or similar elements are designated with the same reference signs, a repeated description of these elements in individual cases being omitted. The figures represent the subject matter of the disclosure only schematically.

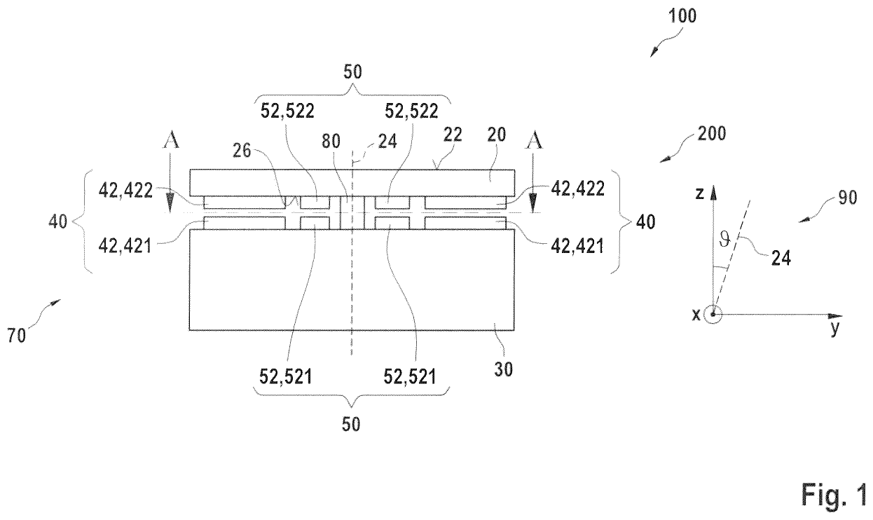

FIG. 1 depicts a side view of an optical component 100 according to the disclosure, which is configured to carry out a method according to the disclosure.

The optical component 100 in this case comprises a mirror element 20 and a substrate 30 for carrying the mirror element 20. The mirror element 20 is in this case mounted on an articulation device 80. To displace the mirror element 20, the optical component 100 comprises a displacement device 200, which has an actuator device 40 for tilting the mirror element 20 and a sensor device 50 for detecting a tilt angle θ of the mirror element 20.

The optical component 100 is arranged, for illustrative purposes, in a three- dimensional Cartesian coordinate system 90. The Cartesian three-dimensional coordinate system 90 comprises an x-axis, a y-axis and a z-axis. The x-axis runs perpendicular to the plane of the drawing towards the observer in FIG. 1. The y-axis runs to the right in FIG. 1. The z-axis runs upwards in FIG. 1.

The mirror element 20 in this case comprises a reflection surface 22 having a surface normal 24 that is perpendicular to the reflection surface 22. Here in the left-hand illustration in FIG. 1, the mirror element 20 is in an unpivoted or untilted state.

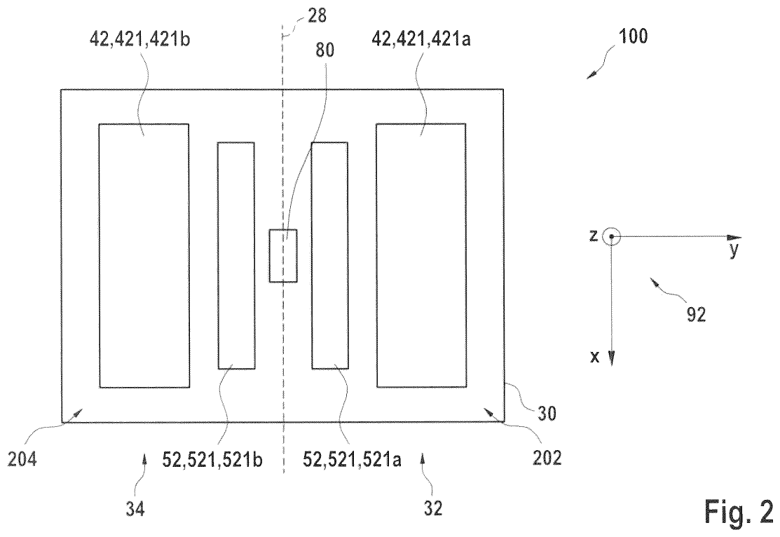

In this case, the substrate 30 is arranged on an x-y plane 92 (cf. FIG. 2), which is defined by the x-axis and the y-axis. In a tilted state, an angle is formed between the surface normal 24 and the z-axis in its running direction, which angle is defined as the tilt angle θ of the mirror element 20 and is illustrated in the right-hand illustration in FIG. 1. This angle is also referred to as polar angle in a spherical coordinate system. The mirror element 20 may in this case be tilted about the x-axis. Of course, the mirror element 20 may also be tilted about the y-axis. The mirror element 20 may likewise be tilted simultaneously about the x-axis and y-axis in order to achieve an azimuth-dependent tilt angle θ.

The actuator device 40 in this case comprises an actuator electrode structure 42 having two active actuator electrodes 421 (cf. FIG. 2), which here are in the form of actuator stator electrodes and are attached to the substrate 30. The actuator electrode structure 42 in this case has two passive actuator electrodes 422 (cf. FIG. 2), which here are in the form of an actuator mirror electrode and are attached to a surface 26 of the mirror element 20 that faces away from the reflection surface 22. In FIG. 1 here, the passive actuator electrodes 422 are each assigned to an active actuator electrode 421. However, the actuator electrode structure 42 may also have a single passive actuator electrode 422 or more than two passive actuator electrodes 422.

The actuator electrodes 421, 422 are configured to exert electrostatic force. They can be in the form of comb electrodes. The active actuator electrodes 421 and the passive actuator electrodes 422 in this case each comprise multiple comb fingers. FIG. 1 reveals that all of the active actuator electrodes 422 are arranged in a common plane 70, which is parallel to the x-y plane 92 and is also referred to as an actuator plane. The actuator device 40, respectively the active actuator electrodes 421 and the passive actuator electrodes 422, in this case form a direct drive for tilting the mirror element 20.

The sensor device 50 in this case comprises a sensor electrode structure 52. It may be seen in FIG. 1 that the sensor electrode structure 52 has two active sensor electrodes 521 (cf. FIG. 2) and two passive sensor electrodes 522 (cf. FIG. 2). In this case, the active sensor electrodes 521 are in the form of sensor stator electrodes and are attached to the substrate 30. It may also be seen in FIG. 1 that the active sensor electrodes 521 are likewise arranged in the common plane 70. The passive sensor electrodes 522 are in this case in the form of sensor mirror electrodes and are attached to the surface 26 of the mirror element 20 that faces away from the reflection surface 22. The sensor electrodes 521, 522 can be in the form of comb electrodes. The active sensor electrodes 521 and the passive sensor electrodes 522 in this case each comprise multiple comb fingers.

FIG. 1 reveals that the articulation device 80 for mounting the mirror element 20 is arranged centrally. It may be in the form of a flexure, such as for example a gimbal flexure. This articulation device 80 defines a mechanical tilt axis 28 (see FIG. 2) of the mirror element 20. The articulation device 80 can define two mechanical tilt axes 28 that intersect at a central point, which is also referred to as tilt point of the mirror element 20. This tilt point is located for example on the surface normal 24 through a central point of the mirror element 20 in the untilted state.

FIG. 2 shows a schematic sectional illustration of the optical component 100 according to FIG. 1 along a sectional plane A in order to illustrate further aspects of the actuator and sensor device 40, 50.

The optical component 100 in FIG. 2 here is arranged in the three-dimensional Cartesian coordinate system 90. The x-axis runs downwards in FIG. 2. The y-axis runs to the right in FIG. 2. The z-axis runs perpendicular to the plane of the drawing towards the observer in FIG. 2. The substrate 30 is in this case arranged on the x-y-plane 92. The common plane 70 is in this case parallel to the x-y plane 90.

As illustrated in FIG. 2, the actuator device 40 or the actuator electrode structure 42 comprises two active actuator electrodes 421, which are arranged on the substrate 30. The sensor device 50 or the sensor electrode structure 52 in this case comprises two active sensor electrodes 521, which are in the form of sensor stator electrodes and are arranged on the substrate 30. All of the actuator and sensor stator electrodes 421, 521 are in this case arranged in the common plane 70.

FIG. 2 reveals that the articulation device 80 defines a tilt axis 28 of the mirror element 20, which tilt axis is aligned parallel to the common plane 70 and corresponds to the x-axis. In FIG. 2 here, the common plane 70 is divided into two sectors by the tilt axis 28, specifically a first sector 32 and a second sector 34. An active actuator electrode 421 and an active sensor electrode 521 are arranged in each sector 32, 34. Each active sensor electrode 522 is assigned an active actuator electrode 421 in the same sector 32, 34.

The tilt axis 28 thus divides the active actuator and sensor electrodes 421, 521 into two electrode pairs, which are each arranged in a sector 32, 34. A first electrode pair 202 in this case comprises an active actuator electrode 421a in the first sector 32 and an active sensor electrode 521a in the first sector 32, while a second electrode pair 204 comprises an active actuator electrode 421b in the second sector 34 and an active sensor electrode 521b in the second sector 34. It may also be seen in FIG. 2 that the first and the second electrode pair 202, 204 are arranged symmetrically with respect to the tilt axis 28. The active sensor electrode 521 and the active actuator electrode 421 are arranged going outwards, in that order, from the tilt axis 28 or the articulation device 80 in the respective sector 32, 34. A different order of the arrangement of the active actuator and sensor electrodes 421, 521 is also possible.

The passive actuator and sensor electrodes 422, 522 not illustrated in FIG. 2 are distributed in the same way.

During operation of the optical component 100 according to FIGS. 1 and 2 with the method according to the disclosure, the two passive sensor electrodes 521 may be subjected to different voltages.

The active actuator electrode 421a in the first sector 32 and the active actuator electrode 421b in the second sector 34 may be controlled differentially. The active sensor electrode 521a in the first sector 32 and the active sensor electrode 521b in the second sector 34 may be connected differentially. They are used to determine the tilt angle relative to the tilt axis 28.

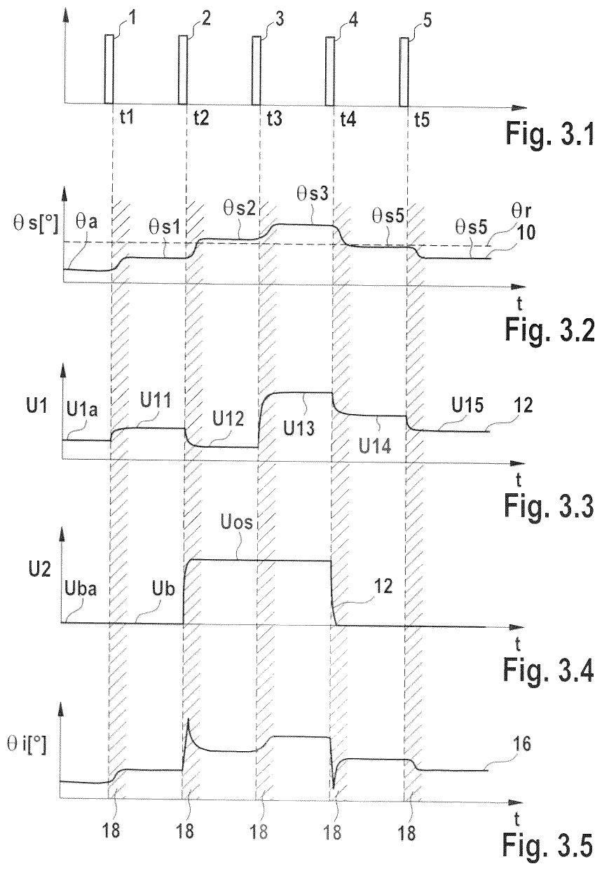

The method according to the disclosure is explained below with reference to FIGS. 3.1 to 3.5. Reference is made in this case to the first electrode pair 202 in the first sector 32. To carry out the method according to the disclosure, provision is made, for the optical component 100, for control electronics, not illustrated, for controlling the optical component 100.

FIG. 3.1 shows a diagram of tilt signals 1 to 5, FIG. 3.2 shows a temporal profile 10 of the target tilt angle Os of the mirror element 20, FIG. 3.3 shows a temporal profile 12 of a first voltage Ul applied to the active actuator electrode 421a in the first sector 32, FIG. 3.4 shows a temporal profile 14 of a second voltage U2 applied to the passive sensor electrode 522a (cf. FIG. 1) in the first sector 32, and FIG. 3.5 shows a temporal profile 16 of the detected tilt angle θi of the mirror element 20.

At a first time t1, the control electronics for controlling the optical component 100 receive a first tilt signal 1 by way of which they are asked to tilt the mirror element 20 from a current tilt angle θa to a first target tilt angle θs1.

At the current tilt angle θa, the first voltage U1 has a current value U1a, while the passive sensor electrode 522a in the first sector 32 is subjected to the second voltage U2. At the current tilt angle θa, as shown in FIG. 3.4, the second voltage U2 corresponds to a bias voltage Ub, which has a current value Uba. The current value Uba of the bias voltage Ub may for example be equal to ground potential. The passive sensor electrode 522b (cf. FIG. 1) in the second sector 34 is in this case likewise subjected to the bias voltage Ub. The bias voltage Ub may assume a constant value, such as for example 0 V. However, the bias voltage Ub may also be in the form of a variable voltage.

The first target tilt angle θs1 is in this case compared with a reference value θr. It may be seen in FIG. 3.2 that the first target tilt angle θs1 is smaller than the reference value θr. To reach the first target tilt angle θs1, only the first voltage U1 is thus set from the current value U1a to a first value U11 used to reach the first target tilt angle θs1, which first value is computed for example by the control electronics on the basis of the sensor data. The second voltage U2, which corresponds to the bias voltage Ub of the passive sensor electrodes 522 in the two sectors 32, 34, remains unchanged at the current value Uba. The first target tilt angle θs1 is reached within a mirror movement phase 18. The tilt angle θ of the mirror element 20 remains constant following the mirror movement phase 18 and is maintained until a new mirror position or a new tilt angle θ has to be moved to.

At a second time t2, the control electronics receive a second tilt signal 2 by way of which they are asked to tilt the mirror element 20 to a second target tilt angle θs2. The second target tilt angle θs2 is in this case compared with the reference value θr. It may be seen in FIG. 3.2 that the second target tilt angle θs2 is greater than the reference value θr. Thus, the passive sensor electrode 522a in the first sector 32 is subjected to an offset voltage Uos in addition to the bias voltage Ub, while the passive sensor electrode 522b in the second sector 34 continues to be subjected to the same bias voltage Ub. The second voltage U2 in this case represents a voltage resulting from the bias voltage Ub and the offset voltage Uos. In FIG. 3.4 here, the offset voltage Uos adopts a predetermined constant value. However, the offset voltage Uos may also be computed on the basis of a difference between the target tilt angle θs of the mirror element 20 and the detected tilt angle θi. Since an additional force for tilting the mirror element 20 is generated by applying the additional offset voltage Uos, the first voltage U1 is reduced to a second value U22, as illustrated in FIG. 3.3.

At a third time t3, the control electronics receive a third tilt signal 3 by way of which they are asked to tilt the mirror element 20 to a third target tilt angle θs3. The third target tilt angle θs3 is in this case compared with the reference value θr. It may be seen in FIG. 3.2 that the third target tilt angle θs3 is greater than the reference value θr. Thus, the passive sensor electrode 522a in the first sector 32 continues to be subjected to the offset voltage Uos in addition to the bias voltage Ub, while the passive sensor electrode 522b in the second sector 34 continues to be subjected to the same bias voltage Ub. To reach the third target tilt angle θs3, a third value U13 of the first voltage Ul is computed and the first voltage U1 is set to this third value U13.

At a fourth time t4, the control electronics receive a fourth tilt signal 4 by way of which they are asked to tilt the mirror element 20 to a fourth target tilt angle θs4. The fourth target tilt angle θs4 is in this case compared with the reference value θr. It may be seen in FIG. 3.2 that the fourth target tilt angle θs4 is smaller than the reference value θr. The offset voltage Uos, which is applied to the passive sensor electrode 522a in the first sector 32 in addition to the bias voltage Ub, is thus no longer required. The passive sensor electrode 522a in the first sector 32 is therefore subjected only to the bias voltage Ub. In other words, the passive sensor electrode 522a in the first sector 32 and the passive sensor electrode 522b in the second sector 34 are in this case subjected to the same bias voltage Ub. A fourth value U24 of the first voltage U1 is computed in this case.

At a fifth time t5, the control electronics receive a fifth tilt signal 5 by way of which they are asked to tilt the mirror element 20 to a fifth target tilt angle θs5. The fifth target tilt angle θs5 is in this case compared with the reference value θr. It may be seen in FIG. 3.2 that the fifth target tilt angle θs5 is smaller than the reference value θr. The offset voltage Uos, which is applied to the passive sensor electrode 522a in the first sector 32 in addition to the bias voltage Ub, is thus likewise not required. The passive sensor electrode 522a in the first sector 32 therefore continues to be subjected only to the bias voltage Ub. The two passive sensor electrodes 522 continue to be subjected to the same bias voltage Ub. A fifth value U15 of the first voltage U1 is computed in this case.

As discussed above, the method according to the disclosure is carried out on the basis of an optical component 100 the displacement device 200 of which is configured to tilt the mirror element 20 about a tilt axis 28, namely with a tilting degree of freedom. What is discussed for example is carrying out the method according to the disclosure by way of a first electrode pair 202 in the first sector 32.

The articulation device 80 may also define a further tilt axis 28 that is aligned parallel to the common plane 70 and corresponds to the y-axis. The two tilt axes 28 defined by the articulation device 80 then correspond in each case to one of the tilting degrees of freedom. The two tilt axes 28 intersect at a central point, which is also referred to as tilt point of the mirror element 20. In this case, the common plane 70 is divided, by the two tilt axes 28, into four sectors 32, 34, also referred to as quadrant. A first active actuator electrode 421, a second active actuator electrode 441 and an active sensor electrode 521 may be arranged in each sector or quadrant. In this case, the first and the second actuator electrode structures and the sensor electrode structure 42, 44, 52 may each exhibit radial symmetry. In this case, the displacement device 200 of the optical component 100 is accordingly configured to tilt the mirror element 20 about two tilt axes 28. The active actuator electrodes 421 of the opposing electrode pairs with respect to the tilt point may in this case be controlled differentially. The active sensor electrodes of the opposing electrode pairs with respect to the tilt point may in this case be connected differentially.

The disclosure is not limited to the exemplary embodiments described here and the aspects highlighted therein. On the contrary, a large number of modifications that are within the ability of a person skilled in the art are possible within the scope specified by the claims.

What is claimed is:

1. A method of operating an optical component comprising a mirror element, a substrate configured to support the mirror element, an actuator device configured to tilt the mirror element about one or two tilt axes, and a sensor device comprising a sensor electrode structure configured to detect a tilt angle of the mirror element based on changes in capacitance, the sensor electrode structure comprising a plurality of active sensor electrodes and a plurality of passive sensor electrodes, the method comprising:
during operation of the optical element:
subjecting the passive sensor electrodes to different voltages and an identical bias voltage; and
for at least one of the passive sensor electrodes, subjecting the at least one passive sensor electrode to an offset voltage in addition to the bias voltage,
wherein the offset voltage is based on a comparison between a target tilt angle of the mirror element and a reference value.

2. The method of claim 1, comprising subjecting the at least one passive sensor electrode to the offset voltage when the target tilt angle of the mirror element is greater than the reference value.

3. The method of claim 2, wherein the offset voltage has a predetermined constant value.

4. The method of claim 2, further comprising determining the offset voltage based on a difference between the target tilt angle of the mirror element and the detected tilt angle of the mirror element.

5. The method of claim 1, wherein the offset voltage has a predetermined constant value.

6. The method of claim 1, further comprising determining the offset voltage based on a difference between the target tilt angle of the mirror element and the detected tilt angle of the mirror element.

7. The method of claim 1, wherein the optical element is an optical element of a mirror array, and the optical element is a mirror.

8. The method of claim 7, wherein the mirror array is within an illumination optical unit configured to guide radiation to an object field.

9. The method of claim 8, wherein the illumination optical unit is within a microlithographic projection exposure apparatus which further comprises a projection optical unit configured to image an illumination portion of the object field into an image field.

10. The method of claim 9, wherein a reticle is in the object field.

11. An optical component, comprising:
a mirror element;
a substrate configured to support the mirror element;
an actuator device configured to tile the mirror element about one or two tilt axes;
a sensor device configured to detect a tilt angle of the mirror element; and
a controller comprising control electronics,
wherein:
i) the sensor device comprises a sensor electrode structure;
ii) the sensor electrode structure comprises a plurality of active sensor electrodes and a plurality of passive sensor electrodes;
iii) the control electronics are configured to:
a) subject the passive sensor electrodes to different voltages and an identical bias voltage;
b) for at least one of the passive sensor electrodes, subject the at least one passive sensor electrode to an offset voltage in addition to the bias voltage; and
iv) the offset voltage is based on a comparison between a target tilt angle of the mirror element and a reference value.

12. The optical component of claim 11, wherein the control electronics are configured to subject the at least one passive sensor electrode to the offset voltage when the target tilt angle of the mirror element is greater than the reference value.

13. The optical component of claim 12, wherein the offset voltage has a predetermined constant value.

14. The optical component of claim 12, wherein the control electronics are configured to determine the offset voltage based on a difference between the target tilt angle of the mirror element and the detected tilt angle of the mirror element.

15. The optical component of claim 11, wherein the offset voltage has a predetermined constant value.

16. The optical component of claim 11, wherein the control electronics are configured to determine the offset voltage based on a difference between the target tilt angle of the mirror element and the detected tilt angle of the mirror element.

17. A mirror array, comprising:
a plurality of optical components according to claim 11,
wherein the optical components are mirrors.

18. An illumination optical unit, comprising:
a mirror array comprising a plurality of optical components according to claim 11,
wherein the optical components are mirrors, and the illumination optical unit is configured to guide radiation to an object field.

19. An apparatus, comprising:
an illumination optical unit comprising a mirror array, the mirror array comprising a plurality of optical components according to claim 11; and
a projection optical unit,
wherein the optical components are mirrors, the illumination optical unit is configured to guide radiation to an object field, the projection optical unit is configured to image an illumination portion of the object field into an image field, and the apparatus is a microlithographic projection exposure apparatus.

20. The method of claim 19, further comprising a reticle is in the object field.
